(19) United States
(12) Patent Application Publication
(10) Pub. No.: US 2016/0237217 A1
(43) Pub. Date: Aug. 18, 2016

(54) ORGANIC-INORGANIC HYBRID PREPOLYMER, ORGANIC-INORGANIC HYBRID POLYMER OBTAINED FROM SAME, SEALING MATERIAL FOR LED ELEMENTS AND SEALING STRUCTURE FOR LED ELEMENTS

(71) Applicant: NIHON YAMAMURA GLASS CO., LTD., Hyogo (JP)

(72) Inventors: Midori SATO, Amagasaki-shi (JP); Takuya SHINDO, Amagasaki-shi (JP); Takuya TAKAYAMA, Amagasaki-shi (JP)

(73) Assignee: Nihon Yamamura Glass Co., Ltd., Amagasaki-shi, Hyogo (JP)

(21) Appl. No.: 15/025,424

(22) PCT Filed: Sep. 30, 2014
(86) PCT No.: PCT/JP14/76059

§ 371 Date: Mar. 28, 2016

(30) Foreign Application Priority Data
Sep. 30, 2013 (JP) 2013-203393

(51) Int. Cl. C08G 77/16; H01L 33/56

(52) U.S. Cl. CPC C08G 77/16; H01L 33/56; C08G 2190/00

(57) ABSTRACT

An organic-inorganic hybrid prepolymer produced by condensation reaction between (A) and one or more compounds (B) selected from (B-1), (B-2), and (B-3):

(A): a polydimethylsiloxane having silanol groups at both ends, a number average molecular weight (Mn) of 10,000 or more and 100,000 or less, and a distribution index of molecular weight (Mw/Mn; Mw is weight average molecular weight) of 1.3 or less;

(B-1): an oligomer of tetraalkoxysilane;

(B-2): a complete or partial hydrolysate of the alkoxy groups of (B-1); and

(B-3): a condensation reaction product of (B-2) and (B-2), or (B-2) and (B-1).

### TECHNICAL FIELD

The present invention relates to a heat resistant organic-inorganic hybrid prepolymer useful for optical use such as a resin for light transmitting sealants, an organic-inorganic hybrid polymer obtained from the same, a sealant for LED elements, and a sealing structure for LED elements.

### BACKGROUND ART

Common light-emitting diodes (LEDs) as optical members are composed of an elastic resin, which is referred to as a sealant, for protecting components such as light emitting element, wire, and reflector. In general, the elastic resin used as the sealant is required to have light extracting properties (transmissivity and adequate refractive index), adhesion (adhesiveness), and heat resistance maintaining properties. In the recent LED field, high brightness and high power LEDs and UV-LEDs are required mainly for on-vehicle headlights and wide region lighting, so that heat resistance demanded of component members such as sealants is increasing year by year.

General-purpose resins such as epoxy resins and silicone resins have been used as elastic resins for the LED sealants. These general-purpose resins have a long history, provide good productivity, processability, and allow low-cost and stable supply.

However, as described above, along with the increase of brightness and power, the light wavelength is shortened, the sealant is required to have light resistance and heat resistance, and high transparency in the UV region. Heat resistant temperature required for high brightness and high power LEDs is increased from prior art 150° C. to 180° C. or higher, and the wiring junction is required to resist higher temperature around 200° C. Under such high temperatures around 200° C., general-purpose resins such as epoxy resins and silicone resins markedly present many problems such as cracking and destruction by heat deterioration, and exfoliation from elements and reflectors by poor adhesion.

Silicone resins are said to have commonly heat resistance of 200° C. or higher. However, the optical member such as the above-described sealant is required to have transparency, so that it is impossible to contain filler. Therefore, there are significant problems such as hardness increase and material destruction during continuous use for 10,000 hours or longer. Adhesion (adhesiveness) is not also sufficient. In addition, these general-purpose resins contain a high proportion of plasticizer, curing agent, and impurity ions, so that abrupt decrease of transmissivity occurs with the approach to the UV wavelength region. In particular, for the recent optical members being used under the conditions of shorter wavelengths and higher brightness and power, the sealant is also required to have high transmissivity in the wavelength range of 200 to 400 nm. Therefore, the market requires a sealant replacing these general-purpose resins.

Regarding the above-described application to recent optical members, in recent years, organic-inorganic hybrid compositions having improved properties by incorporation of an inorganic component in a siloxane polymer are developed.

Organic-inorganic hybrid compositions are materials having flexibility, water repellency, and releasability of the polyorganosiloxane main chain structure as an organic component, heat resistance, and strength of the mechanical structure of an inorganic component (for example, see Non-Patent Literature 1). The cured product of the organic-inorganic hybrid composition has high heat resistance and flexibility at continuous working temperature of 200° C. or higher, and marked electrical properties such as high electric insulation and low dielectricity at high frequency (Patent Literatures 1 to 4, Non-Patent Literature 1).

The organic-inorganic hybrid material has been examined to be used as the sealant for a semiconductor device, and wire bonding which are installed in a laser diode (LD), a light emitting diode (LED), an LED print head (LPH), a charge coupled device (CCD), and an insulated gate bipolar transistor (IGBT), or the like.

### CITATIONS LIST

### Patent Literatures

Patent Literature 1: JPH 1-113429 A

Patent Literature 2: JPH 2-182728 A

Patent Literature 3: JPH 4-227731 A

Patent Literature 4: JP 2009-292970 A

### Non-Patent Literature

Non-Patent Literature 1: G. Philipp and H. Schmidt, J. Non-Cryst. Solids 63,283 (1984)

### SUMMARY OF INVENTION

### Technical Problems

However, the above-described polyorganosiloxane organic-inorganic hybrid materials are not suitable for the use in LED having wavelengths shortened to the blue region, because they may have relatively high heat resistance, but have many problems with the light transmissivity in the UV region, and thus cause rapid deterioration of the transmissivity in the wavelength region at 400 nm or less because of the influences of organic substances and impurities contained in the materials.

In addition, according to a proposal, as the organic-inorganic hybrid material, an organic-inorganic hybrid prepolymer is prepared by condensation reaction between polydimethylsiloxane having silanol group(s) at one end or both ends (hereinafter referred to as PDMS) and metal alkoxide accompanied by the formation of water or alcohol, and the organic-inorganic hybrid prepolymer is heat-cured to make an organic-inorganic hybrid polymer.

The PDMS used for the organic-inorganic hybrid material is generally produced by polycondensation, and has a relatively wide molecular weight distribution. In particular, if the synthesis time is prolonged for increasing the molecular weight, the molecular weight of PDMS tends to be uneven because of temperature ununiformity. More specifically, in the scaling up, the improvement of the temperature uniformity in the synthesis vessel is important.

The cured product of the prepolymer obtained from the PDMS having a broad molecular weight distribution has molecular chains with different lengths in the cured body, and thus has no homogeneity in the light transmission path and easily causes light scattering. Accordingly, the prior art organic-inorganic hybrid material has better heat resistance and adhesion properties than silicone resin and epoxy resin, but its light extraction properties (light transmissivity) are not satisfactory.

Examples of the method for making PDMS having a narrow molecular weight distribution include the living polymerization method. This method allows preparation of PDMS having a relatively narrow molecular weight distribution, but the solvent such as toluene used during synthesis of PDMS, and a small amount of low molecular siloxane as a raw material remain, which can result in the decrease of the transmissivity.

In addition, for high brightness and high power LEDs, heat resistance is important for maintaining the transmissivity. The heat resistance includes the performance relating to the height of the upper working temperature, and the performance relating to the temperature gap occurring when the high temperature during the use of the product including LEDs decreases to the room temperature after stopping the product. More specifically, it includes heat resistance relating to the stress on the adhesion layer of each member brought by the phenomenon which is referred to as thermal stress. The components of LEDs are metals such as elements and wire bonding, ceramics and resins of the package, sealant resins, and cover glass, and have different coefficients of linear expansion. Therefore, as the gap between the high working temperature and the temperature at the time of stopping increases, thermal stress being induced between different materials increases. In general, the adhesive layer and sealant are markedly influenced by the thermal stress, and thus high power LEDs require the use of a resin having flexibility able to relax the thermal stress.

### Solutions to Problems

The present invention is intended to provide a heat-resistant organic-inorganic hybrid prepolymer and a sealant obtained from the polymer, the prepolymer solves the above-described problems with prior art, and is useful as a sealant for high brightness and high power optical members, in particular LEDs.

As a result of studies by the inventors, it was found that the molecular weight distribution of polydimethylsiloxane having silanol groups at both ends, which is the main raw material, is important for the improvement of the light transmissivity in the short wavelength region corresponding to the UV light. Evaluation of molecular weight distribution uses the ratio of weight average molecular weight (Mw) to number average molecular weight (Mn) (Mw/Mn) as the distribution index of molecular weight. It was found that the transmissivity in the wavelength range of 300 nm or less markedly decreases when the Mw/Mn is more than 1.7. When the Mw/Mn is 1.7 or less, light transmissivity of 60% or more can be maintained even when the wavelength is 250 nm or less, but when the Mw/Mn is more than 1.3, problems with heat resistance maintaining properties at high temperatures of 200° C. or higher may occur. In consideration of heat resistance maintaining properties at high temperatures of 200° C. or higher, the distribution index of molecular weight (Mw/Mn) is preferably 1.3 or less, and more preferably 1.1 or less.

In the present description, the weight average molecular weight (Mw) and the number average molecular weight (Mn) are measured by the gel permeation chromatograph (GPC method) using polystyrene as the reference material, and tetrahydrofuran as the eluent.

As the means for solving the above-described problems, the present invention provides an organic-inorganic hybrid prepolymer (C) produced by condensation reaction between the following (A) and one or more compounds (B) selected from the group consisting of the following (B-1), (B-2), and (B-3).

(A): a polydimethylsiloxane having silanol groups at both ends, a number average molecular weight (Mn) of 10,000 or more and 100,000 or less, and a distribution index of molecular weight (Mw/Mn; Mw is weight average molecular weight) of 1.7 or less.

(B-1): an oligomer of tetraalkoxysilane.

(B-2): a complete or partial hydrolysate of the alkoxy groups of (B-1).

(B-3): a condensation reaction product of (B-2) and (B-2), or (B-2) and (B-1).

The organic-inorganic hybrid prepolymer (C) of the present invention is preferably obtained by adding 0.5 to 8 mol of the (B-1) to 1 mol of the (A), and subjecting them to condensation reaction.

The residual amount of the organic solvent in the (A) is preferably 50 ppm or less, and more preferably 20 ppm or less.

The (B-1) is preferably a linear tetramer to decamer, and its purity is preferably 65% by mass or more.

The present invention further provides an organic-inorganic hybrid polymer (F) as a cured product obtained by heat-curing the organic-inorganic hybrid prepolymer (C).

In the organic-inorganic hybrid polymer (F) of the present invention, the organic-inorganic hybrid prepolymer (C) is preferably heat-cured in the presence of an organometallic compound-containing solution (D).

The organometallic compound-containing solution (D) is preferably a solution containing an organometallic compound (E) and the (A).

The organometallic compound (E) is preferably one ore more compounds selected from the group consisting of organic acid metal salts, metal alkoxides, alkylmetal compounds, acetylacetonate metal complexes, ethyl acetoacetate metal complexes, and metal complexes prepared by substituting one or more alkoxy groups of a metal alkoxide with acetylacetonate or ethyl acetoacetate, and particularly preferably at least one selected from the group consisting of mixtures of zirconium carboxylate and zinc carboxylate, and mixtures of zirconyl carboxylate and zinc carboxylate.

In the organic-inorganic hybrid polymer (F) of the present invention, the mixing ratio of the organic-inorganic hybrid prepolymer (C) to the organometallic compound-containing solution (D) is preferably from 100:0.1 to 100:20 in terms of the mass ratio of (C):(D).

When the organic-inorganic hybrid polymer (F) is a plate-shaped body having a thickness of 0.5 mm, it preferably transmits 60% or more of light having a wavelength of 200 nm, and 95% or more of light having a wavelength of 250 nm in the thickness direction.

The organic-inorganic hybrid polymer (F) preferably has an elongation at break of 150% or more as measured by the tensile test in accordance with JIS K6251.

The present invention further provides an LED element sealant containing the organic-inorganic hybrid prepolymer (C), and an LED element sealing structure composed of LED elements sealed by the organic-inorganic hybrid polymer (F).

### Advantageous Effects of Invention

[Actions]

The polydimethylsiloxane (PDMS) (A) having silanol groups at both ends used in the present invention must have a narrow molecular weight distribution whose distribution index of molecular weight (Mw/Mn) is 1.7 or less.

The method for preparing the PDMS (A) is not limited, but the method for narrowing the molecular weight distribution is preferably a living polymerization method. The distribution index of molecular weight of the PDMS prepared by the living polymerization method can be decreased to 1.7 or less, further 1.3 or less, and even further 1.1 or less. The distribution index of molecular weight of the PDMS prepared even by other methods than the living polymerization method can be decreased to 1.7 or less by removing the low molecular components.

However, the PDMS (A) by the living polymerization method satisfies the distribution index of molecular weight, but aromatic hydrocarbon organic solvents such as toluene and xylene remain, so that light transmissivity in the wavelength region from 200 to 300 nm may deteriorate. Therefore, the removal of low molecular components and organic solvents having marked absorption in the UV region is important. The removal of the low molecular components and solvents from the PDMS (A) as the raw material is achieved by distillation or washing. Common distillation can cause condensation of the PDMS (A) during heating, and the average molecular weight markedly increases. Therefore, in order to prevent condensation of the PDMS (A), the use of a method leaving no heat history in the raw material, such as vacuum distillation at a relatively low temperature, or the method using a thin film distillation apparatus or a molecular distillation apparatus is preferred.

The number average molecular weight (Mn) of the PDMS (A) is 10,000 or more and 100,000 or less. When the number average molecular weight (Mn) is 10,000 or more and 100,000 or less, the final heat-cured product can have a low hardness and flexibility, and offer an elongation at break of 150% or more in the tesile test. The heat-cured product having such mechanical properties can relax thermal stress, and maintain heat resistance over a long term. The number average molecular weight is more preferably 15,000 or more and 40,000 or less. From the viewpoint of heat resistance maintaining properties, the number average molecular weight is more preferably 20,000 or more, and the distribution index of molecular weight (Mw/Mn) is preferably 1.3 or less, and more preferably 1.1 or less.

In the present invention, as the inorganic components, one or more compounds (B) selected from the group consisting of (B-1) an oligomer of tetraalkoxysilane, (B-2) a complete or partial hydrolysate of the alkoxy groups of an oligomer of tetraalkoxysilane, and (B-3) a condensation reaction product of complete or partial hydrolysates of the alkoxy groups of an oligomer of tetraalkoxysilane, or a condensation reaction product of a complete or partial hydrolysate of the alkoxy groups of an oligomer of tetraalkoxysilane and an oligomer of tetraalkoxysilane are subjected to reaction. In addition to the narrow molecular weight distribution of the PDMS (A), the organic-inorganic hybrid prepolymer (C) produced by condensation reaction between the PDMS (A) and the compound (B) can homogenize the curing reaction, and can reduce the curing time.

When the organic-inorganic hybrid prepolymer (C) alone is heat-cured, in comparison with the case where the organic-inorganic hybrid prepolymer (C) is heat-cured (at 150° C. to 180° C., for about 3 to 5 hours) in the presence of the organometallic compound-containing solution (D), treatment at a higher temperature, for example, heat treatment at 60° C. to 100° C. for about 1 hour, and then at 200° C. to 220° C. for about 3 to 5 hours is necessary. However, from the viewpoint of light transmissivity, the organic-inorganic hybrid prepolymer (C) alone may be heat-cured.

In addition, in the present invention, the amount of the catalyst used for the condensation reaction in the synthesis of the organic-inorganic hybrid prepolymer (C), and the amount of the curing agent used for curing reaction of the organic-inorganic hybrid prepolymer (C) in heating curing in the presence of the organometallic compound-containing solution (D) can be markedly reduced, whereby deterioration of light transmissivity can be prevented.

[Effect]

The present invention provides an organic-inorganic hybrid polymer which forms a cured product (sealing body) having high light transmissivity in the UV region, marked heat resistance (flexibility), and being resistant to cracking by thermal stress. The above-described polymer is useful as a sealant for high brightness and high power optical members, in particular LEDs.

The organic-inorganic hybrid cured product produced from the PDMS having a uniform molecular weight distribution has higher heat resistance than prior art material, and, according to the present invention, maintains high light transmissivity and low hardness for a long term, and exhibits heat resistance and weather resistance for 5,000 hours or longer.

### BRIEF DESCRIPTION OF DRAWINGS

FIG. 1 is a graph showing the spectral transmittance of Examples 1 to 3.

FIG. 2 is a graph showing the spectral transmittance of Examples 1, 4, and 6.

FIG. 3 is a graph showing the spectral transmittance of Examples 1 and 5.

FIG. 4 is a graph showing the spectral transmittance of Example 1 and Comparative Examples 1 to 4.

FIG. 5 is a graph showing the spectral transmittance of Example 1 and Comparative Examples 1, 5, and 6.

FIG. 6 is a graph showing the spectral transmittance of Example 1 and Reference Example 1.

### DESCRIPTION OF EMBODIMENTS

The present invention is described below in detail.

<Polydimethylsiloxane (A) Having Silanol Group at Both Ends>

The polydimethylsiloxane (PDMS) used for the synthesis of the organic-inorganic hybrid prepolymer (C) of the present invention have silanol groups at both ends which can react with the following compound (B), and is represented by the following general formula:

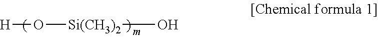

wherein m is an integer of 135 to 1351.

The PDMS (A) has a number average molecular weight (Mn) of 10,000 or more and 100,000 or less. When the number average molecular weight (Mn) is 10,000 or more, the cured product composed mainly of the organic-inorganic hybrid prepolymer (C) of the present invention has high mechanical properties (flexibility), and has an elongation at break of 150% or more, preferably 200% or more as measured by a tensile test. Therefore, heat resistance maintaining properties allowing thermal shock relaxation of temperature change from high temperature to low temperature is secured, and cracking of the cured product (sealing body) is reduced. In addition, when the number average molecular weight (Mn) is 100,000 or less, it is not necessary to dilute high viscosity PDMS with a predetermined solvent, whereby contraction by volatilization of the solvent is eliminated. In consideration of heat resistance maintaining properties etc, the number average molecular weight is more preferably 15,000 or more and 40,000 or less, and even more preferably 20,000 or more and 40,000 or less.

The PDMS (A) used has a distribution index of molecular weight (Mw/Mn) of 1.7 or less. The distribution index of molecular weight (Mw/Mn) of the PDMS (A) is preferably 1.3 or less, and more preferably 1.1 or less.

When the distribution index of molecular weight (Mw/Mn) of the PDMS (A) is 1.7 or less, the cured product (organic-inorganic hybrid polymer (F)) of the organic-inorganic hybrid prepolymer (C) can maintain light transmissivity of 60% or more at wavelengths of 250 nm or less. Furthermore, when the distribution index of molecular weight (Mw/Mn) of the PDMS (A) is 1.3 or less, the cured product (organic-inorganic hybrid polymer (F)) of the organic-inorganic hybrid prepolymer (C) having marked heat resistance maintaining properties at high temperatures of 200° C. or higher is obtained.

The method for preparing the above-described PDMS (A) is not particularly limited, but the synthesis by the living anion polymerization method using alkyl lithium as the initiator allows the preparation of the PDMS having a distribution index of molecular weight (Mw/Mn) of 1.3 or less, further 1.1 or less, namely a narrow molecular weight distribution.

The PDMS prepared by the living anion polymerization method contains a residual organic solvents such as toluene used for reaction. The organic solvents remaining in the PDMS may deteriorate light transmissivity in the wavelength range of 200 to 380 nm, so that the organic solvents remaining in the PDMS must be removed. In order to achieve good light transmissivity in the wavelength range of 200 to 380 nm, the residual amount of the organic solvents in the PDMS (A) is preferably 50 ppm or less, and more preferably 20 ppm or less. Examples of the method for removing organic solvents from the PDMS (A) include distillation. However, ordinary distillation causes condensation of the PDMS (A) during heating, and thus increases the average molecular weight of the PDMS (A). Therefore, in order to prevent condensation of the PDMS (A), vacuum distillation at a relatively low temperature, or distillation using a thin film distillation apparatus or a molecular distillation apparatus is preferred.

<Measurement of Average Molecular Weight>

The average molecular weight was measured by the gel-permeation chromatograph (GPC method), and the ratio of weight average molecular weight (Mw) to number average molecular weight (Mn) was used as the distribution index of molecular weight. Polystyrene was used as the reference material, and the molecular weight in terms of polystyrene was measured.

The molecular weight in terms of polystyrene as measured by the GPC method is carried out under the following measurement conditions:

a) measurement instrument: SIC Autosampler Model 09
Sugai U-620 COLUMN HEATER
Uniflows UF-3005S2B2

b) detector: MILLIPORE Waters 410
Differential Refractometer

c) column: Shodex KF806M, 2 pieces

d) oven temperature: 40° C.

e) eluent: tetrahydrofuran (THF) 1.0 mL/min

f) reference material: polystyrene

g) injection amount: 100 μL

h) concentration: 0.020 g/10 mL

i) sample preparation: Using THF containing 0.2% by weight of 2,6-di-tert-butyl-p-phenol (BHT) as the solvent, the sample was dissolved by stirring at room temperature.

j) correction: The difference of the BHT peak between the calibration curve measurement and sample measurement was corrected, and the molecular weight was calculated.

<Compound (B)>

The compound (B) composing the inorganic component used for the synthesis of the organic-inorganic hybrid prepolymer of the present invention is the oligomer of tetraalkoxysilane (B-1) which can smoothly react with the end silanol groups of polydimethylsiloxane.

The oligomer of tetraalkoxysilane (B-1) has the following general formula:

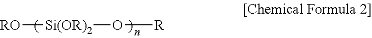

wherein the oligomer of tetraalkoxysilane is preferably linear tetramer to decamer (n in Chemical Formula 2 is preferably an integer of 4 to 10). In addition, R in Chemical Formula 2 represents an alkyl group having 1 to 3 carbon atoms, preferably a methyl group, ethyl group, n-propyl group, or isopropyl group, and is most preferably an ethyl group from the viewpoint of reactivity and reaction control.

In the condensation reaction with the PDMS (A), the oligomer of tetraalkoxysilane (B-1) can turn into the complete or partial hydrolysate (B-2) of alkoxy groups of the oligomer by complete or partial hydrolysis of the alkoxy groups of the oligomer. In addition, the condensation reaction product (3-3) can be produced by the reaction between complete or partial hydrolysates (B-2) of alkoxy groups of the oligomer of tetraalkoxysilane, or between the oligomer of tetraalkoxysilane (B-1) and the complete or partial hydrolysate (B-2) of alkoxy groups of the oligomer of tetraalkoxysilane. In consideration of these facts, in the synthesis of the organic-inorganic hybrid prepolymer of the present invention, as the compound (B) composing the inorganic component, one or more compounds selected from the group consisting of the (B-1), (B-2) and (B-3) are subjected to reaction.

A tetraalkoxysilane monomer is not preferred as the compound (B) composing the inorganic component in the present invention, because the tetraalkoxysilane monomer tends to cause polycondensation by itself to form cluster particles of a reticularly crosslinked polycondensate, and thus decrease the light transmissivity. In comparison with the tetraalkoxysilane monomer, the oligomer has low volatility, low reactivity, and thus moderately promotes reaction with PDMS, and thus is preferred as the inorganic component used for the synthesis of the organic-inorganic hybrid prepolymer of the present invention. However, when the oligomer of tetraalkoxysilane is smaller than tetramer (n in Chemical Formula 2 is less than 4), it has reactivity equivalent to that of a tetraalkoxysilane monomer, and when it is greater than decamer (n in Chemical Formula 2 is more than 10), reactivity with PDMS decreases.

The oligomer of tetraalkoxysilane (B-1) may contain impurities composed mainly of a tetraalkoxysilane monomer, and the impurities affect the high light transmissivity, heat resistance, weather resistance, and mechanical properties of the cured product to be finally obtained (organic-inorganic hybrid polymer (F)). In particular, as described above, tetraalkoxysilane monomers form cluster particles to decrease the light transmissivity. Accordingly, in consideration of the high light transmissivity, heat resistance, weather resistance, and mechanical properties of the cured product, the oligomer of tetraalkoxysilane (B-1) preferably contains few impurities, namely has high purity. Specifically, the purity of the oligomer of tetraalkoxysilane (B-1) is preferably 65% by mass or more, more preferably 90% by mass or more, and most preferably 95% by mass or more.

<Organic-Inorganic Hybrid Prepolymer (C)>

[Preparation of Organic-Inorganic Hybrid Prepolymer (C) Soil

In the present invention, as described above, the PDMS (A) and one or more compounds (B) selected from the group consisting of the (B-1), (B-2) and (B-3) based on an oligomer of tetraalkoxysilane are subjected to condensation reaction, thereby producing the organic-inorganic hybrid prepolymer (C).

The condensation reaction usually uses an organometallic condensation catalyst such as an organic tin compound such as dibutyltin dilaurate and dibutyltin bis(2-ethylhexanoate), or an organic titanium compound such as titanium tetra-2-ethylhexoside, and may use an acid catalyst such as hydrochloric acid, or an alkali catalyst such as ammonia for the purpose of hydrolysis.

When the condensation reaction is carried out, in order to achieve stable hydrolysis of the oligomer of tetraalkoxysilane (B-1), the hydrolysis and condensation reaction are preferably carried out by heating the reaction vessel filled with inert gas. Examples of the inert gas include nitrogen gas or Group 18 element (for example, helium, neon, argon, krypton, and xenon) which is rare gas. In addition, these gases may he used in combination. The method of hydrolysis may be selected from various methods, such as dropping or spraying an adequate amount of water, or introducing water vapor to the reaction system.

The organic-inorganic hybrid prepolymer (C) is obtained by subjecting a mixture containing the compound (B) based on the oligomer of tetraalkoxysilane and the PDMS (A) to condensation reaction in the presence of the condensation catalyst under the inert gas atmosphere. In the condensation reaction, in order to uniformly and efficiently react the PDMS (A) and the compound (B), tert-butyl alcohol may be added to the mixture of the PDMS (A) and the compound (B).

As described above, in the compound (B) which has been subjected to controlled hydrolysis, some alkoxy groups of the oligomer of tetraalkoxysilane are possibly turned to OH groups, and heating in the presence of inert gas causes condensation reaction with the silanol groups at the both ends of the PDMS (A) accompanied by dehydration or dealcoholization. The use of the compound (B) based on the oligomer of tetraalkoxysilane allows smooth condensation reaction between the PDMS (A) and compound (B) without accelerating the condensation of the tetraalkoxysilane monomer alone, and improves the crosslinking density and mechanical properties of the cured product.

The use of other metal alkoxides or chelates such as zirconium- or titanium-based ones as the inorganic component corresponding to tetraalkoxysilane allows the improvement of properties such as the refractive index, but the transmissivity is never good because of the formation of color developable structure. Along with the uniform progress of the reaction between the PDMS (A) and the compound (B) based on the oligomer of tetraalkoxysilane, the cured product becomes uniform, whereby high transmissivity is achieved.

If the compound (B) based on the oligomer of tetraalkoxysilane is exposed to excessive moisture, it accelerates the condensation between complete or partial hydrolysates (B-2) of alkoxy groups of the oligomer of tetraalkoxysilane, or between the complete or partial hydrolysate (B-2) of alkoxy groups of the oligomer of tetraalkoxysilane and the oligomer of tetraalkoxysilane (B-1), whereby clusters of the inorganic component is readily formed. Accordingly, the inert gas atmosphere having a strictly controlled moisture content is extremely important for stably synthesizing the organic-inorganic hybrid prepolymer (C) by the uniform reaction between the PDMS (A) and the compound (B) based on the oligomer of tetraalkoxysilane.

[Mixing Ratio]

The mixing ratio of the PDMS (A) to the compound (B-1) ((A)/(B-1)) is preferably from 0.125 to 2 in terms of the molar ratio (0.5 to 8 mol of the compound (B-1) is added to 1 mol of PDMS (A)), and more preferably from 0.125 to L25 in terms of the molar ratio (0.8 to 8 mol of the compound (B-1) is added to 1 mol of PDMS (A)).

When the molar ratio of (A)/(B-1) is within the above-described range, the condensation reaction is smoothly carried out, gelation during or after reaction hardly occurs, and thus the formation of gelled product hardly occurs, so that stable sol without residual low molecular weight siloxane is obtained.

The molar ratio referred herein is calculated based on the number average molecular weight (Mn) of PDMS measured by gel permeation chromatograph (GPC method) using polystyrene as the reference material and tetrahydrofuran as the eluent, and the purity and average molecular weight of the oligomer of tetraalkoxysilane.

<Organometallic Compound-Containing Solution (D)>

In order to appropriately obtaining the organic-inorganic hybrid polymer (F) of the present invention, it is preferred that the organic-inorganic hybrid prepolymer (C) be mixed with the organometallic compound-containing solution (D). The organometallic compound-containing solution (D) is usually prepared by dissolving the below-described organometallic compound (E) in a solvent.

[Organometallic Compound (E)]

The organometallic compound (E) used in the organometallic compound-containing solution (D) of the present invention may be an ordinary PDMS curing agent, and is, for example, at least one selected from organometallic compounds such as Sn, Ti, Al, Zn, Zr, and Bi-based ones.

The organometallic compound (E) may be an organic acid salt (particularly carboxylate), an alkoxide, an alkylmetal compound, an acetylacetonate complex, an ethyl acetoacetate complex, or a metal complex prepared by substituting some alkoxy groups of a metal alkoxide with acetylacetonate or ethyl acetoacetate of the above-described metals, and specific examples thereof include zinc octylate (zinc 2-ethylhexanoate), zirconium octylate (zirconium 2-ethylhexanoate), zirconyl octylate (zirconyl 2-ethylhexanoate), dibutyltin dilaurate, dibutyltin diacetate, dibutyltin bis(acetylacetonate), tetra(2-ethylhexyl) titanate, titanium tetra-n-butoxide, titanium tetraisopropoxide, titanium diisopropoxy bis(ethyl acetoacetate), titanium tetraacetylacetonate, titanium di-2-ethylhexoxy bis(2-ethyl-3 -hydroxyhexoxide), titanium diisopropoxy bis(acetylacetonate), zirconium tetra-n-propoxide, zirconium tetra-n-butoxide, zirconium tetraacetylacetonate, zirconium tributoxy monoacetylacetonate, and zirconium dibutoxy bis(ethyl acetoacetate).

The organometallic compound is preferably a compound having no π conjugated system within the molecule, in consideration of the light transmissivity in the UV wavelength range.

Furthermore, in order to make a uniform molecular structure from the surface to the inside of the organic-inorganic hybrid polymer (F) which is a cured product, the combination of a zirconium carboxylate such as zirconium octylate (zirconium 2-ethylhexanoate) and a zinc carboxylate such as zinc octylate (zinc 2-ethylhexanoate), and/or combination of a zirconyl carboxylate such as zirconyl octylate (zirconyl 2-ethylhexanoate) and a zync carboxylate such as zinc octylate (zinc 2-ethylhexanoate) is particularly preferred.

[Solvent]

The solvent used in the organometallic compound-containing solution (D) of the present invention is preferably an organic solvent which will not affect the light transmissivity of short wavelength, and is preferably tert-butyl alcohol with which the PDMS (A) and compound (B) are favorably dissolved.

[Mixing of PDMS]

The organometallic compound-containing solution (D) of the present invention may contain a mixture of the organometallic compound (E) and PDMS. The PDMS used for mixing with the organometallic compound (E) is preferably the same as the PDMS (A) used for the synthesis of the prepolymer. The number average molecular weight is preferably from 10,000 to 100,000, more preferably 15,000 or more and 40,000 or less, and even more preferably 20,000 or more and 40,000 or less. In addition, the distribution index of molecular weight (Mw/Mn) is preferably 1.7 or less, more preferably 1.3 or less, and even more preferably 1.1 or less.

[Diluent]

In the organometallic compound-containing solution (D), the mixing ratio of the organometallic compound (E) to diluent is usually preferably from 3:97 to 50:50 in terms of the mass ratio. The diluent herein means the component other than the organometallic compound (E) in the organometallic compound-containing solution (D), namely the organic solvent such as tert-butyl alcohol, PDMS, oligomer of tetraalkoxysilane or the like. When the proportion of the organometallic compound (E) is below the above-described range, the organometallic compound (E) cannot markedly achieve the effect of a curing agent, and when the proportion exceeds the range, the organometallic compound-containing solution (D) becomes unstable.

<Organic-Inorganic Hybrid Polymer (F)>

The organic-inorganic hybrid polymer (F) of the present invention is a cured product obtained by heat-curing the sol of the prepolymer (C) alone, or heat-curing a mixture of the sol of the prepolymer (C) and the organometallic compound-containing solution (D) in the presence of the organometallic compound-containing solution (D).

The distribution index of molecular weight (Mw/Mn) of the PDMS (A) used for the synthesis of the prepolymer (C) is 1.7 or less, preferably 1.3 or less, and more preferably 1.1 or less, whereby condensation reaction between the PDMS (A) and the compound (B) is smoothly completed, so that heat-curing of the polymer (F) proceeds more efficiently than prior art. Furthermore, when the sol of the prepolymer (C) is heat-cured in the presence of the organometallic compound-containing solution (D), it can be treated at low temperature and in a short time.

[Mixing Ratio]

When the prepolymer (C) and the organometallic compound-containing solution (D) are mixed to obtain the polymer (F), the mixing ratio of the prepolymer (C) to the organometallic compound-containing solution (D) is commonly preferably from 100:0.1 to 100:20 in terms of the mass ratio of (C):(D). When the proportion of the organometallic compound-containing solution (D) is below this range, the homogenization effect on the curing reaction of the prepolymer (C) becomes insufficient, and when the proportion of the organometallic compound-containing solution (D) exceeds this range, heat resistance (weight reduction) deteriorates.

<Light Emitting Device Sealing Structure>

The major uses of the prepolymer (C) and polymer (F) according to the present invention include the materials of sealant. Specific examples of the sealant include LEDs composed of a light emitting element coated with a sealant for protecting the light emitting surface. With respect to the element mounted on the top surface of the substrate, the terminal provided on the substrate surface and the terminal provided on the element are electrically connected through wire bonding, and the element and wire are covered by the sealant.

In recent years, some LED structural bodies include light diffusion glass or ceramics for light diffusion on the top of the light emitting element, wherein the sealant also works as the adhesive layer for the light diffusion glass or ceramics.

When a sealant composed mainly of the organic-inorganic hybrid prepolymer (C) of the present invention is used, the sealant is applied to or injected into at least the emitting surface of the optical element, thereby sealing the optical element. At this time, attention must be paid so as to prevent inclusion of air bubbles into the sealant, and quick vacuum defoamation treatment is preferred after sealing. Thereafter, the element which the sealant has been applied to or injected into is heated in a high temperature furnace (also referred to as “oven”), and the sealant is gelated, thereby making a sealing structure of the desired shape.

The sealant composed of the prepolymer (C) and polymer (F) according to the present invention maintains transparency and translucency of the sealant, even after exposure to near-ultraviolet light for a long term. Furthermore, in an environment at high temperatures from 150° C. to 180° C., the sealant according to the present invention provides a high quality semiconductor device, because it will not cause destruction phenomenon such as cracking or exfoliation by heat generated from the semiconductor element or wire bonding of the LED light emitting element, and will not cause problems such as destruction of the element, breaking of wire bonding, and deterioration of insulation.

As described above, the prepolymer (C) and polymer (F) according to the present invention are useful as heat-resistant optical materials. For an optical member, special emphasis is often placed on transmissivity. In addition, the prepolymer (C) and polymer (F) in the present invention have higher heat resistance than silicone materials, achieve high light transmissivity by narrowing the molecular weight distribution width of the PDMS (A), and achieve high transparency in the UV region. Therefore, they are useful as UV-LEDs, high power LED sealants, and optical members used in the wavelength range from 200 to 400 nm.

### EXAMPLES

The present invention is further specifically described below with reference to Examples, but the present invention will not be limited to these examples.

In Examples, “part” and “%” are based on the mass (parts by mass, % by mass), unless otherwise specified. In addition, the toluene content in PDMS was measured by gas chromatography.

### Examples 1 to 6

[Preparation of Prepolymer (C) Sol Solution]

A reactor equipped with a stirrer, a thermometer, and a dropping means was thoroughly filled with nitrogen gas. The nitrogen gas was produced using a nitrogen gas producing equipment (UNX-200, manufactured by Japan UNIX Co., Ltd.).

Subsequently, the PDMS (A) having silanol groups at both ends and the oligomer of tetraalkoxysilane (B-1) were placed in the reactor sufficiently filled with the nitrogen gas, and stirred for 30 minutes at room temperature.

Subsequently, a condensation catalyst was placed therein, the temperature was increased from the room temperature to 100° C. at a rate of 10° C./minute, and the object was further allowed to react at 100° C. for 1 hour. Thereafter, the object was allowed to cool to room temperature, thereby obtaining a sol solution of the prepolymer (C). During the reaction, the nitrogen gas was kept flowing.

The type, mass and molar ratio ((A):(B-1)) of the PDMS (A) and the oligomer (B-1) used in each Example, and also the species and amount of condensation catalyst used in each Example are as described below.

### Example 1

PDMS (A); FM9926, manufactured by JNC Corporation (solvent was removed by a molecular distillation apparatus), number average molecular weight (Mn)=23,000, distribution index of molecular weight (Mw/Mn)=1.10, toluene content=less than 10 ppm.

Oligomer (B-1); ethyl silicate, Silicate 45, manufactured by Tama Chemicals Co., Ltd.: linear octamer to decamer oligomer of tetraethoxysilane (oligomer purity: 95% by mass), average molecular weight=1282.

Molar ratio; 85.0 g of PDMS (A), 15.0 g of oligomer (B-1) (Silicate 45), and the molar ratio of FM9926 to oligomer purity of Silicate 45 is 1:3.

Condensation catalyst; dibutyltin dilaurate 0.01 g.

### Example 2

PDMS (A); FM9925, manufactured by INC Corporation (solvent was removed by a molecular distillation apparatus), number average molecular weight (Mn)=10,000, distribution index of molecular weight (Mw/Mn)=1.12, toluene content=less than 10 ppm.

Oligomer (B-1); ethyl silicate, Silicate 40, manufactured by Tama Chemicals Co., Ltd.: linear tetramer to hexamer oligomer of tetraethoxysilane (oligomer purity: 70% by mass), average molecular weight=745.

Molar ratio; 90.4 g of PDMS (A), 9.6 g of oligomer (B-1) (Silicate 40), and the molar ratio of FM9925 to oligomer purity of Silicate 40 is 1:1.

Condensation catalyst; dibutyltin dilaurate 0.02 g.

### Example 3

PDMS (A); FM9927, manufactured by JNC Corporation (solvent was removed by a molecular distillation apparatus), number average molecular weight (Mn)=32,000, distribution index of molecular weight (Mw/Mn)=1.09, toluene content=less than 10 ppm.

Oligomer (B-1); ethyl silicate, Silicate 45, manufactured by Tama Chemicals Co., Ltd.: linear octamer to decamer oligomer of tetraethoxysilane (oligomer purity: 95% by mass), average molecular weight=1282.

Molar ratio; 88.8 g of PDMS (A), 11.2 g of oligomer (B-1) (Silicate 45), and the molar ratio of FM9927 to oligomer purity of Silicate 45 is 1:3.

Condensation catalyst; dibutyltin dilaurate 0.01 g.

### Example 4

PDMS (A); YF3057, manufactured by Momentive Performance Materials Inc., number average molecular weight (Mn)=32,000, distribution index of molecular weight (Mw/Mn)=1.63, toluene content=less than 10 ppm.

Oligomer (B-1); ethyl silicate, Silicate 40, manufactured by Tama Chemicals Co., Ltd.: linear tetramer to hexamer oligomer of tetraethoxysilane (oligomer purity: 70% by mass), average molecular weight=745.

Molar ratio; 85.7 g of PDMS (A), 14.3 g of oligomer (B-1) (Silicate 40), and the molar ratio of YF3057 to oligomer purity of Silicate 40 is 1:5.

Condensation catalyst; dibutyltin dilaurate 0.01 g.

### Example 5

PDMS (A); FM9926, manufactured by JNC Corporation (solvent was removed by a molecular distillation apparatus), number average molecular weight (Mn)=23,000, distribution index of molecular weight (Mw/Mn)=1.10, toluene content=less than 10 ppm.

Oligomer (B-1); ethyl silicate, Silicate 45, manufactured by Tama Chemicals Co., Ltd.: linear octamer to decamer oligomer of tetraethoxysilane (oligomer purity: 95% by mass), average molecular weight=1282.

Molar ratio; 81.0 g of PDMS (A), 19.0 g of oligomer (B-1) (Silicate 45), and the molar ratio of FM9926 to oligomer purity of Silicate 45 is 1:4.

Condensation catalyst; dibutyltin dilaurate 0.01 g.

### Example 6

PDMS (A); FM9927, manufactured by JNC Corporation (solvent was removed by a molecular distillation apparatus), number average molecular weight (Mn)=32,000, distribution index of molecular weight (Mw/Mn)=1.09, toluene content=less than 10 ppm.

Oligomer (B-1); ethyl silicate, Silicate 40, manufactured by Tama Chemicals Co., Ltd.: linear tetramer to hexamer oligomer of tetraethoxysilane (oligomer purity after purification: 90% by mass), average molecular weight=745.

Molar ratio; 97.7 g of PDMS (A), 2.3 g of oligomer (B-1) (Silicate 40), and the molar ratio of FM9927 to oligomer purity of Silicate 40 is 1:0.9.

Condensation catalyst; dibutyltin dilaurate 0.01 g.

[Preparation of Organometallic Compound-Containing Solution (D)]

Polydimethylsiloxane (PDMS) having silanol groups at both ends, the organometallic compound (E), and a solvent were placed in a reactor other than that for the prepolymer (C), heated to 60° C., and stirred for 30 minutes in the atmosphere, thereby obtaining the organometallic compound-containing solution (D).

The PDMS, organometallic compound (E), solvent, and their loadings used in each Example are as described below.

### Example 1

PDMS; the same as that used in the above-described [Preparation of prepolymer (C) sol solution] (Example 1), 27.2 g.

Organometallic compound (E); zinc 2-ethylhexanoate (Nikka Octix Zinc, manufactured by Nihon Kagaku Sangyo Co., Ltd., Zn: 18%) 1.24 g, and zirconyl 2-ethylhexanoate (Nikka Octix Zirconium, manufactured by Nihon Kagaku Sangyo Co., Ltd., Zr: 12%) 1.55 g.

Solvent; tert-butyl alcohol 3.0 g

### Example 2

PDMS; the same as that used in the above-described [Preparation of prepolymer (C) sol solution] (Example 2), 24.9 g.

Organometallic compound (E); zinc 2-ethylhexanoate (Nikka Octix Zinc, manufactured by Nihon Kagaku Sangyo Co., Ltd., Zn: 18%) 2.26 g, and zirconyl 2-ethylhexanoate (Nikka Octix Zirconium, manufactured by Nihon Kagaku Sangyo Co., Ltd., Zr: 12%) 2.84 g.

Solvent; tert-butyl alcohol 3.0 g

### Example 3

PDMS; the same as that used in the above-described [Preparation of prepolymer (C) sol solution] (Example 3), 28.2 g.

Organometallic compound (E); zinc 2-ethylhexanoate (Nikka Octix Zinc, manufactured by Nihon Kagaku Sangyo Co., Ltd., Zn: 18%) 0.80 g, and zirconyl 2-ethylhexanoate (Nikka Octix Zirconium, manufactured by Nihon Kagaku Sangyo Co., Ltd., Zr: 12%) 1.00 g.

Solvent; tert-butyl alcohol 3.0 g

### Example 4

PDMS; the same as that used in the above-described [Preparation of prepolymer (C) sol solution] (Example 4), 17.7 g.

Organometallic compound (E); zinc 2-ethylhexanoate (Nikka Octix Zinc, manufactured by Nihon Kagaku Sangyo Co., Ltd., Zn: 18%) 1.00 g, and zirconyl 2-ethylhexanoate (Nikka Octix Zirconium, manufactured by Nihon Kagaku Sangyo Co., Ltd., Zr: 12%) 1.26 g.

Solvent; tert-butyl alcohol 2.0 g

### Example 6

PDMS; the same as that used in the above-described [Preparation of prepolymer (C) sol solution] (Example 6), 28.2 g.

Organometallic compound (E); zinc 2-ethylhexanoate (Nikka Octix Zinc, manufactured by Nihon Kagaku Sangyo Co., Ltd., Zn: 18%) 0.80 g, and zirconyl 2-ethylhexanoate (Nikka Octix Zirconium, manufactured by Nihon Kagaku Sangyo Co., Ltd., Zr: 12%) 1.00 g.

Solvent; tert-butyl alcohol 3.0 g

[Preparation of Mixture (F′)]

The prepolymer (C) sol solution and the organometallic compound-containing solution (D) were mixed at a predetermined mass ratio, thereby obtaining the mixture (F′).

In Example 5, the prepolymer (C) sol solution was used alone without adding the organometallic compound-containing solution (D).

The mass ratio of the prepolymer (C) sol solution to the organometallic compound-containing solution (D) in each Example is as described below in terms of the mass ratio of (C):(D).

(Example 1); 100:10 (mass ratio)

(Example 2); 100:10 (mass ratio)

(Example 3); 100:5 (mass ratio)

(Example 4); 100:15 (mass ratio)

(Example 6); 100:20 (mass ratio)

### Comparative Examples 1, 5, and 6

[Preparation of Prepolymer (c) Sol Solution]

PDMS (a) having silanol groups at both ends and the oligomer of tetraalkoxysilane (b-1) were placed in a reactor under the same conditions as in Examples 1 to 6, and stirred for 30 minutes at room temperature.

Subsequently, a condensation catalyst was placed therein, the temperature was increased from the room temperature to 140° C. at a rate of 10° C./minute, and the mixture was further allowed to react at 140° C. for 1 hour. Thereafter, the mixture was allowed to cool to room temperature, thereby obtaining a sol solution of the prepolymer (c). During the reaction, the nitrogen gas was kept flowing.

The type, mass and molar ratio ((a):(b-1)) of the PDMS (a) and the oligomer (b-1) used in each Comparative Example, and also the species and amount of condensation catalyst used in each Comparative Example are as described below.

### Comparative Example 1

PDMS (a); 12.9 g of PDMS (al, YF3800, manufactured by Momentive Performance Materials Inc., number average molecular weight (Mn)=6,000) and 64.3 g of PDMS (a2, XF3905, manufactured by Momentive Performance Materials Inc., number average molecular weight (Mn)=20,000) were mixed, thereby having the number average molecular weight (Mn)=20,000, the distribution index of molecular weight (Mw/Mn)=2.02, and toluene content=less than 10 ppm.

Oligomer (b-1); ethyl silicate, Silicate 40, manufactured by Tama Chemicals Co., Ltd.: linear tetramer to hexamer oligomer of tetraethoxysilane (oligomer purity: 70% by mass), average molecular weight=745.

Molar ratio; 77.2 g of PDMS (a), 22.8 g of oligomer (b-1) (Silicate 40), and the molar ratio of YF3800, XF3905 and oligomer purity of Silicate 40 is 0.4:0.6:4.

Condensation catalyst; dibutyltin dilaurate 0.02 g.

### Comparative Example 5

PDMS (a); 79.3 g of PDMS (a1, YF3057, manufactured by Momentive Performance Materials Inc., number average molecular weight (Mn)=32,000) and 6.4 g of PDMS (a2, YF3800, manufactured by Momentive Performance Materials Inc., number average molecular weight (Mn)=6,000) were mixed, thereby having the number average molecular weight (Mn)=32,000, the distribution index of molecular weight (Mw/Mn)=2.57, and toluene content=less than 10 ppm.

Oligomer (b-1); ethyl silicate, Silicate 45, manufactured by Tama Chemicals Co., Ltd.: linear octamer to decamer oligomer of tetraethoxysilane (oligomer purity: 95% by mass), average molecular weight=1282.

Molar ratio; 85.7 g of PDMS (a), 14.3 g of oligomer (b-1) (Silicate 45), and the molar ratio of YF3057, YF3800 and oligomer purity of Silicate 45 is 07:0.3:3.

Condensation catalyst; dibutyltin dilaurate 0.01 g.

### Comparative Example 6

PDMS (a); YF3800, manufactured by Momentive Performance Materials Inc., number average molecular weight (Mn)=6,000, distribution index of molecular weight (Mw/Mn)=1.81, toluene content=less than 10 ppm.

Oligomer (b-1); ethyl silicate, Silicate 45, manufactured by Tama Chemicals Co., Ltd.: linear octamer to decamer oligomer of tetraethoxysilane (oligomer purity: 95% by mass), average molecular weight=1282.

Molar ratio; 81.6 g of PDMS (a), 18.4 g of oligomer (b-1) (Silicate 45), and the molar ratio of YF3800 to oligomer purity of Silicate 45 is 1:1.

Condensation catalyst; dibutyltin dilaurate 0.05 g.

[Preparation of organometallic compound-containing solution (d)] The polydimethylsiloxane (PDMS) having silanol groups at both ends, organometallic compound (e), and solvent were placed in a reactor other than that for the prepolymer (c), heated to 60° C., and stirred for 30 minutes in the atmosphere, thereby obtaining the organometallic compound-containing solution (d).

The PDMS, organometallic compound (e), solvent, and their loadings used in each Comparative Example are as described below.

### Comparative Example 1

PDMS; the same as that used in the above-described [Preparation of prepolymer (c) sot solution] (Comparative Example 1), 27.2 g.

Organometallic compound (e); zinc 2-ethylhexanoate (Nikka Octix Zinc, manufactured by Nihon Kagaku Sangyo Co., Ltd., Zn: 18%) 1.24 g, and zirconyl 2-ethylhexanoate (Nikka Octix Zirconium, manufactured by Nihon Kagaku Sangyo Co., Ltd., Zr: 12%) 1.55 g.

Solvent; tert-butyl alcohol 3.0 g

### Comparative Example 5

PDMS; the same as that used in the above-described [Preparation of prepolymer (c) sol solution] (Comparative Example 5), 28.2 g.

Organometallic compound (e); zinc 2-ethylhexanoate (Nikka Octix Zinc, manufactured by Nihon Kagaku Sangyo Co., Ltd., Zn: 18%) 0.80 g, and zirconyl 2-ethylhexanoate (Nikka Octix Zirconium, manufactured by Nihon Kagaku Sangyo Co., Ltd., Zr: 12%) 1.00 g.

Solvent; tert-butyl alcohol 3.0 g

### Comparative Example 6

PDMS; the same as that used in the above-described [Preparation of prepolymer (c) sol solution] (Comparative Example 6), 22.4 g.

Organometallic compound (e); zinc 2-ethylhexanoate (Nikka Octix Zinc, manufactured by Nihon Kagaku Sangyo Co., Ltd., Zn: 18%) 3.39 g, and zirconyl 2-ethylhexanoate (Nikka Octix Zirconium, manufactured by Nihon Kagaku Sangyo Co., Ltd., Zr: 12%) 4.25 g.

Solvent; tert-butyl alcohol 3.0 g

[Preparation of Mixture (f′)]

The sol solution of the prepolymer (c) and the organometallic compound-containing solution (d) were mixed at a predetermined mass ratio, thereby obtaining the mixture (f′).

The mass ratio of the sol solution of the prepolymer (c) to the organometallic compound-containing solution (d) in each Comparative Example is as follows in terms of the mass ratio between (c):(d).

(Comparative Example 1); 100:10 (mass ratio)

(Comparative Example 5); 100:10 (mass ratio)

(Comparative Example 6); 100:15 (mass ratio)

### Comparative Examples 2 to 4

The following products were used as prior art LED sealants.

Comparative Example 2: two-part curing type transparent silicone sealant (IVSM-4500 transparent silicone, manufactured by Momentive Performance Materials Inc., cured at 150° C. for 1 hour).

Comparative Example 3: acryl-modified silicone resin (Super XG Gold Super Transparent Type, manufactured by Cemedine Co., Ltd., cured at room temperature).

Comparative example 4: transparent epoxy resin (Excel-epo, manufactured by Cemedine Co., Ltd., (two-part type), high transparency, cured at room temperature).

[Evaluation of Light Transmissivity 1]

[Making of Evaluation Sample]

The mixture (F) of each of Examples 1 to 4 and 6 was sandwiched between quartz glass sheets at a thickness of 0.5 mm, cured by heating at 180° C. for 5 hours, thereby making the evaluation sample of the polymer (F) as a cured product to obtain the samples of Examples 1 to 4 and 6.

In Example 5, the organometallic compound-containing solution (D) was not added, and the prepolymer (C) was sandwiched between quartz glass sheets at a thickness of 0.5 mm, cured by heating at 220° C. for 5 hours, thereby making an evaluation sample of the polymer (F) as a cured product to obtain the sample of Example 5.

The mixtures (f′) of Comparative Examples 1, 5, and 6 were cured in the same manner as in Examples 1 to 4, and 6, thereby making the evaluation samples of the polymer (f) as a cured product to obtain the samples of Comparative Examples 1, 5, and 6.

In Comparative Examples 2 to 4, each sealant was sandwiched between quartz glass sheets at a thickness of 0.5 mm, cured, thereby making each evaluation sample to obtain the samples of Comparative Examples 2 to 4.

[Measurement Method]

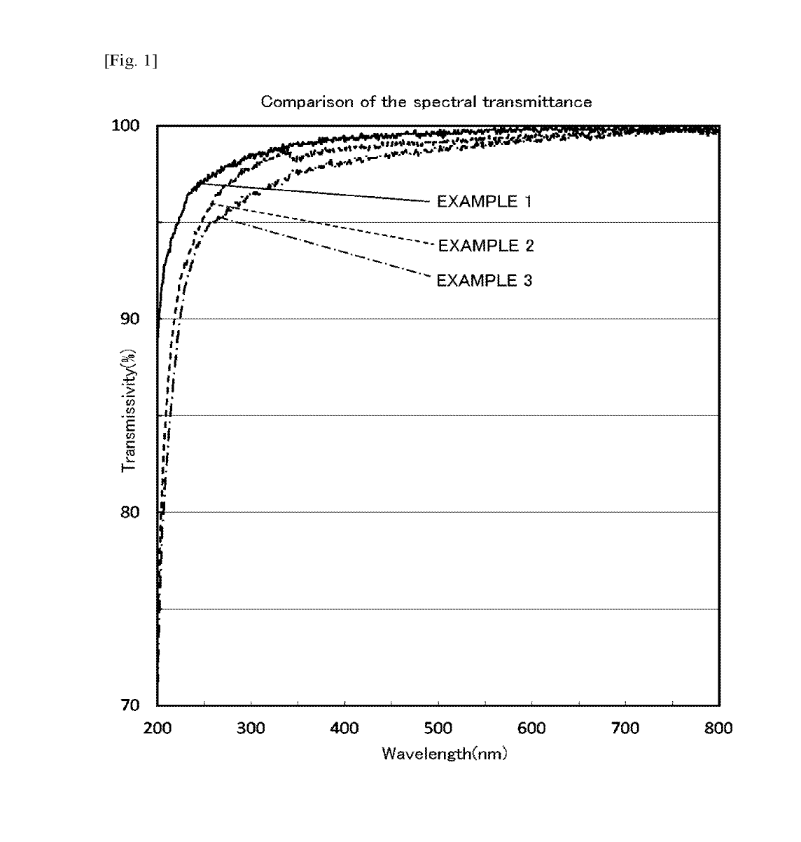

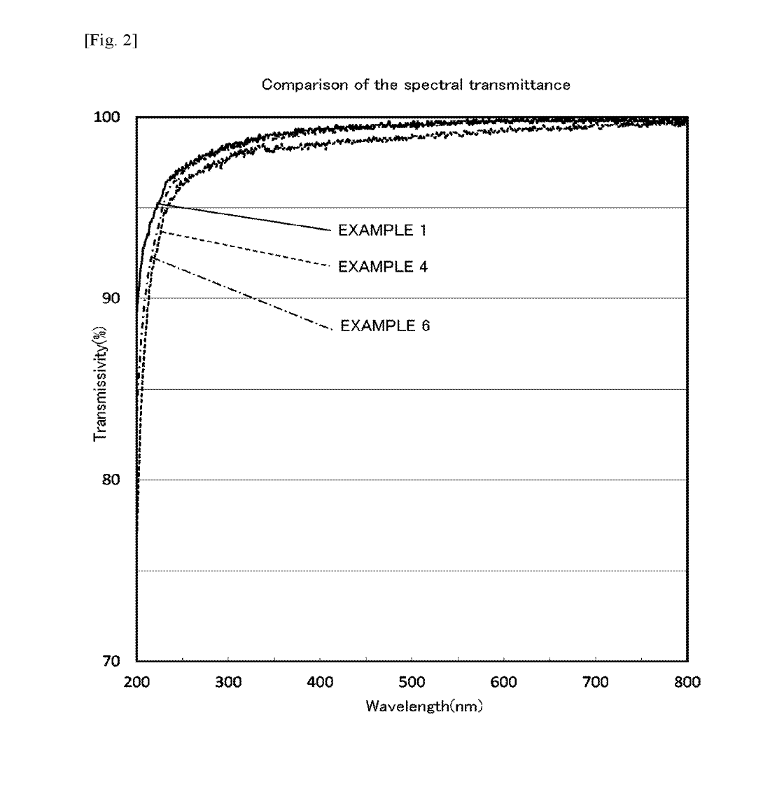

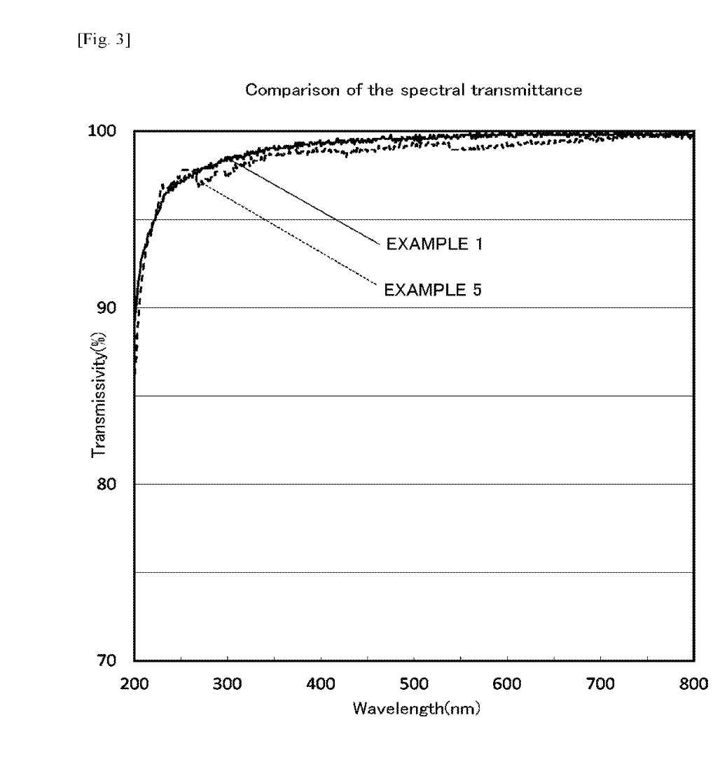

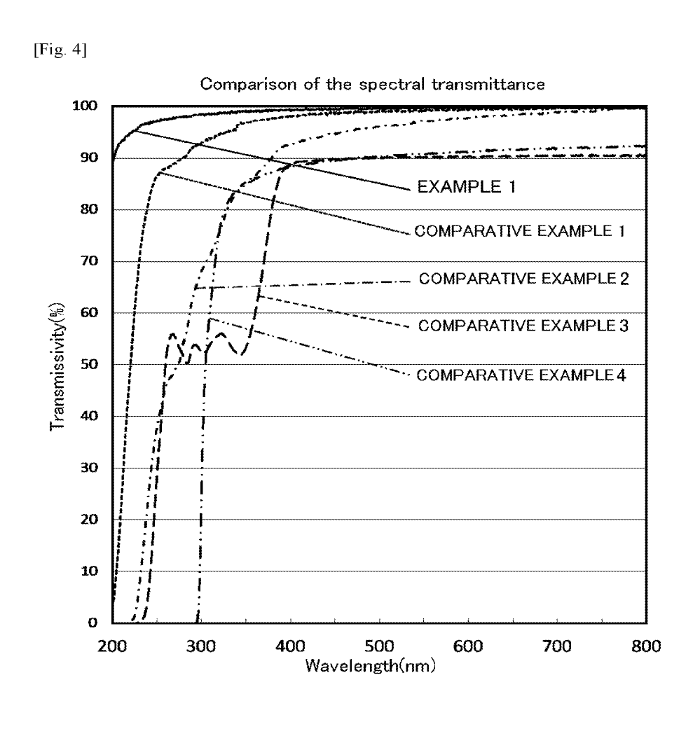

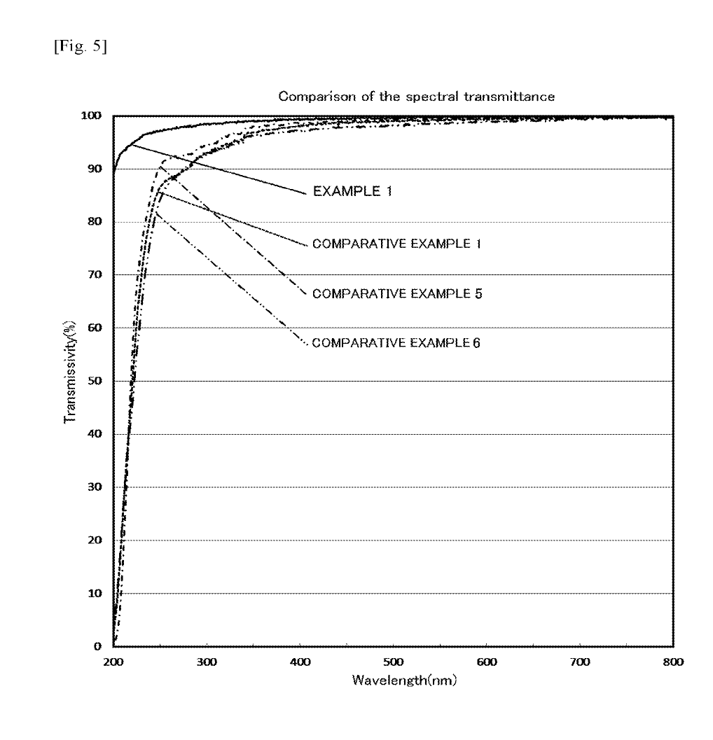

The samples of Examples 1 to 6 and Comparative Examples 1 to 4 were measured for the transmissivity at the wavelengths 200 nm to 800 nm using a spectrophotometer U-4100 (manufactured by Hitachi, Ltd.). The results for Examples 1 to 3 are shown in the graph of FIG. 1, the results for Examples 1, 4, and 6 are shown in the graph of FIG. 2, the results for Examples 1 and 5 are shown in the graph of FIG. 3, the results for Example 1 and Comparative Examples 1 to 4 are shown in the graph of FIG. 4, and the results for Example 1 and Comparative Examples 1, 5, and 6 are shown in the graph of FIG. 5.

The transmissivity was obtained by previously measuring the transmissivity of quartz glass as reference, and subtracting the reference from the measurement result.

[Result of Evaluation 1]

The graphs of FIGS. 1 to 3 indicate that Examples 1 to 6 have marked light transmissivity.

The graph of FIG. 4 indicates that Comparative Example 1 had a transmissivity of almost 0% at 200 nm, while Example 1 had a transmissivity of 89% at 200 nm. In Comparative Example 1, the transmissivity at 300 nm was 93%, and the transmissivity at 400 nm was 98%, while in Example 1, the transmissivity at 300 nm was 98%, and the transmissivity at higher wavelengths was almost 100%. It is thus indicated that Example 1 using the PDMS having a distribution index of molecular weight of 1.10 (the solid line in FIG. 4) has higher light transmissivity than Comparative Example 1 using the PDMS having a distribution index of molecular weight of 2.02 (the chain line in FIG. 4) in the entire wavelength range.

In addition, the graph of FIG. 4 indicates that Example 1 has no absorption at specific wavelengths in comparison with Comparative Examples 2 to 4, and thus will not cause deterioration of the sealant such as yellowing or white turbidity.

The graph of FIG. 5 indicates that Comparative Examples 5 and 6 have as low light transmissivity (less than 95%) in the UV region (at 250 nm) as Comparative Example 1 in comparison with Example 1, and have lower light transmissivity than Example 1.

[Light Transmissivity Evaluation 2]

The samples of Examples 1 to 6 and Comparative Examples 1 to 4 were stored for a long period at 180° C., and the change in transmissivity was measured. The results are shown in Table 1.

The transmissivity was obtained by previously measuring the transmissivity of quartz glass as reference, and subtracting the reference from the measurement result.

TABLE 1
Change in light transmissivity during storage at 180° C.

| | | Elapsed time | | | | | | | | | | | |
|---|---|---|---|---|---|---|---|---|---|---|---|---|---|
| | | 0 hour | | | | 200 hours | | | | 1000 hours | | | |
| | | Measured wavelength | | | | | | | | | | | |
| | | 200 nm | 300 nm | 400 nm | 500 nm | 200 nm | 300 nm | 400 nm | 500 nm | 200 nm | 300 nm | 400 nm | 500 nm |
| Light | Example 1 | 88.96 | 98.53 | 99.16 | 99.47 | 91.76 | 98.53 | 99.66 | 99.99 | 92.87 | 99.19 | 99.57 | 99.88 |
| transmissivity (%) | Example 2 | 74.42 | 97.78 | 98.84 | 99.26 | 81.76 | 98.30 | 99.26 | 99.58 | 81.93 | 97.87 | 99.15 | 99.26 |
| | Example 3 | 70.98 | 96.35 | 98.12 | 98.64 | 76.16 | 97.21 | 99.10 | 99.10 | 87.04 | 98.63 | 99.41 | 99.10 |
| | Example 4 | 76.26 | 97.70 | 98.54 | 99.06 | 80.82 | 97.82 | 99.41 | 99.09 | 88.81 | 98.83 | 99.37 | 99.09 |
| | Example 5 | 85.42 | 97.40 | 98.85 | 99.17 | 89.98 | 97.52 | 99.73 | 99.20 | 95.78 | 99.42 | 99.69 | 99.20 |
| | Example 6 | 83.42 | 98.19 | 99.15 | 99.57 | 83.35 | 98.40 | 98.83 | 99.25 | 80.45 | 98.28 | 99.79 | 99.89 |
| | Comparative | 2.99 | 93.05 | 97.86 | 99.04 | 8.00 | 94.09 | 99.01 | 99.67 | 8.33 | 93.64 | 99.23 | 99.89 |
| | Example 1 | | | | | | | | | | | | |
| | Comparative | 0.00 | 68.15 | 92.56 | 96.23 | 0.00 | 63.28 | 90.98 | 96.55 | 0.00 | 49.28 | 75.98 | 90.85 |
| | Example 2 | | | | | | | | | | | | |

| | | | | | | |
|---|---|---|---|---|---|---|
| Comparative | 0.00 | 52.40 | 88.90 | 90.00 | Colored | Colored, cracked |
| Example 3 | | | | | | |
| Comparative | 0.00 | 25.30 | 88.30 | 90.20 | Colored, cracked | — |
| Example 4 | | | | | | |

[Results of Evaluation 2]

The results in Table 1 indicate that Examples 1 to 6 caused no change in the transmissivity even after exposure to high temperature (180° C.) for a long time. On the other hand, Comparative Examples 2 to 4 caused problems such as marked change in the transmissivity, coloring, and cracking after storage at a high temperature.

### Reference Example 1

[Preparation of Prepolymer (C′) Sol Solution]

The prepolymer (C′) sol solution was prepared in the same manner as the prepolymer (C) sol solution in Examples 1 to 6.

The type, mass and molar ratio ((A′):(B′-1)) of the PDMS (A′) having silanol groups at both ends and tetraalkoxysilane oligomer (B′-1) used in Reference Example 1, and also the species and amount of condensation catalyst used in Reference Example 1 are as described below.

PDMS(A′) ; FM9926, manufactured by JNC Corporation, residual solvent untreated, number average molecular weight (Mn)=22,000, distribution index of molecular weight (Mw/Mn)=1.15, toluene content=100 ppm.

Oligomer (B′-1); ethyl silicate, Silicate 45, manufactured by Tama Chemicals Co., Ltd.,: linear octamer to decamer oligomer of tetraethoxysilane (oligomer purity: 95% by mass), average molecular weight=1282.

Molar ratio; 84.5 g of PDMS (A′), 15.5 g of oligomer (B′-1) (Silicate 45), and the molar ratio of FM9926 to oligomer purity of Silicate 45 is 1:3.

Condensation catalyst; dibutyltin dilaurate 0.02 g.

[Preparation of Organometallic Compound-Containing Solution (D′)]

The organometallic compound-containing solution (D′) was prepared in the same manner as the organometallic compound-containing solution (D) of Examples 1 to 4 and 6.

The PDMS, organometallic compound (E′), solvent, and their loadings used in Reference Example 1 are as described below.

PDMS; the same as that used in the above-described [Preparation of prepolymer (C′) sol solution] (Reference Example 1), 27.2 g.

Organometallic compound (E′); zinc 2-ethylhexanoate (Nikka Octix Zinc, manufactured by Nihon Kagaku Sangyo Co., Ltd., Zn: 18%) 1.24 g, and zirconyl 2-ethylhexanoate (Nikka Octix Zirconium, manufactured by Nihon Kagaku Sangyo Co., Ltd., Zr: 12%) 1.55 g.

Solvent; tert-butyl alcohol 3.0 g

[Preparation of Mixture (F″)]

The prepolymer (C′) sol solution and the organometallic compound-containing solution (D′) were mixed at 100:10 (mass ratio), thereby obtaining the mixture (F″).

[Light Transmissivity Evaluation 3]

The mixture (F″) was sandwiched between quartz glass sheets at a thickness of 0.5 mm, cured by heating at 180° C. for 5 hours, thereby making an evaluation sample to obtain the sample of Reference Example 1.

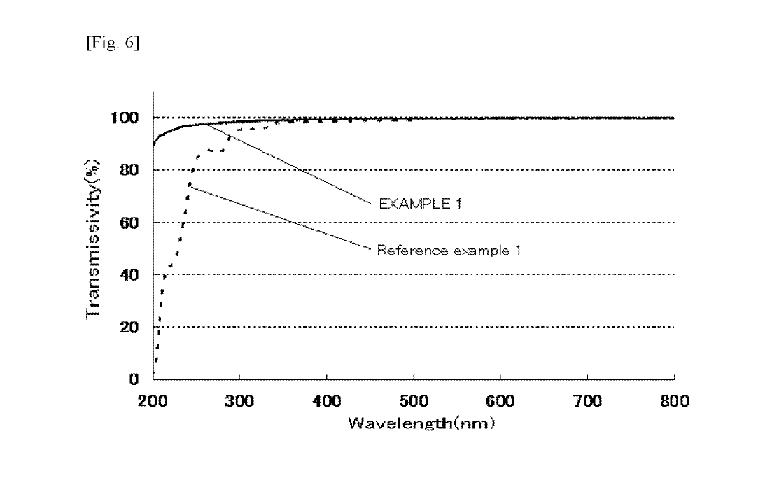

The transmissivity was measured in the same manner as in [Light transmissivity evaluation 1]. The result is shown in the graph of FIG. 6 and Table 2.

[Result of Evaluation 3]

The graph of FIG. 6 and Table 2 indicate that Example 1 (the solid line in FIG. 6) having a reduced toluene content showed no absorption attributable to organic solvents such as toluene remaining in polydimethylsiloxane in comparison with Reference Example 1 (the thick chain line in FIG. 6), indicating that the problems such as yellowing or white turbidity of the sealant hardly occur.

[Evaluation of Tensile Test]

[Making of Sample]

The mixture (F′) or the mixture (f′) was placed in a Teflon (registered trademark) petri dish, and cured by heating at 180° C. for 5 hours to make a sheet having a thickness of 1 mm. In Example 5, the organometallic compound-containing solution (D) was not added, and the prepolymer (C) was cured by heating at 220° C. for 5 hours. Samples of No. 7 dumbbell were made in accordance with JIS K6251, and used as the samples of Examples 1 to 6 and Comparative Examples 1, 5, and 6.

[Measurement Method]

The samples of Example 1 and Comparative Example 1 were stored at 180° C. for 0 to 2000 hours, and other samples (Examples 2 to 6, and Comparative Examples 5 and 6) were stored at 180° C. for 0 to 200 hours, and measured (N=3) for the elongation at break using a tensile tester (Autograph, Shimadzu Co., Ltd.) in accordance with JIS K6251. The results are shown in Table 2.

[Evaluation Result of Tensile Test]

As shown in Table 2, in Examples 1 to 6, the elongation at break was higher than 200% before storage at 180° C. Even after storage at 180° C. for 200 hours, the elongation at break remained higher than 200% was maintained except for in Example 2, and 150% or more in Example 2. Furthermore, in Example 1, the elongation at break was higher than 200% even storage at 180° C. for 2000 hours.

On the other hand, in Comparative Example 1, the elongation at break was 150% or more before storage at 180° C., and became about 100% after storage at 180° C. for 200 hours. Furthermore, after storage at 180° C. for 2000 hours, the elongation at break was less than 100%.

In Comparative Example 5, the elongation at break was more than 200% before storage at 180° C., and became 150% or more after storage at 180° C. for 200 hours.

In Comparative Example 6, the elongation at break was less than 150% before and after storage at 180° C. for 200 hours.

Accordingly, Examples as the organic-inorganic hybrid materials of the present invention maintained mechanical properties (elongation at break) even at high temperatures, indicating that they have higher heat resistance than the materials of Comparative Examples.

[Evaluation of Presence or Absence of Cracking]

[Evaluation Method]

In Examples 1 to 4 and 6, and Comparative Examples 1, 5, and 6, the mixtures (F′, f′) prepared were placed in a glass petri dish, and cured by heating at 180° C. for 5 hours, thereby obtaining samples having a thickness of 1 mm.

In Example 5, the prepolymer (C) was place in a glass petri dish, and cured by heating at 220° C. for 5 hours, thereby obtaining a sample having a thickness of 1 mm.

The sample was stored at 180° C. or 200° C. for 1,000 hours, cooled to room temperature, and the presence or absence of cracking was confirmed at the time. The result is shown in Table 2.

TABLE 2

| | | Example 1 | Example 2 | Example 3 | Example 4 | Example 5 | Example 6 |
|---|---|---|---|---|---|---|---|
| PDMS having | Mn | 23,000 | 10,000 | 32,000 | 32,000 | 23,000 | 32,000 |
| silanol groups | Mw/Mn | 1.10 | 1.12 | 1.09 | 1.63 | 1.10 | 1.09 |
| at both ends | | | | | | | |
| oligomer of TEOS | | n = 8~10 | n = 4~6 | n = 8~10 | n = 4~6 | n = 8~10 | n = 4~6 |
| (n-mer: linear) | | | | | | | |
| PDMS/oligomer of TEOS | | 1/3 | 1/1 | 1/3 | 1/5 | 1/4 | 1/0.9 |
| (molar ratio) | | | | | | | |
| Toluene content (ppm) *1 | | Less than 10 | Less than 10 | Less than 10 | Less than 10 | Less than 10 | Less than 10 |
| Light | 200 nm | 89.0 | 74.4 | 71.0 | 76.3 | 85.4 | 83.4 |
| transmissivity | 250 nm | 97.3 | 95.3 | 95.0 | 96.2 | 97.7 | 96.9 |
| (%) (thickness | 300 nm | 98.5 | 97.8 | 96.3 | 97.7 | 97.4 | 98.2 |
| 0.5 mm) | 350 nm | 99.2 | 98.4 | 97.5 | 98.2 | 98.6 | 98.8 |
| | 400 nm | 99.2 | 98.8 | 98.1 | 98.5 | 98.9 | 99.1 |

| | | | | | | |
|---|---|---|---|---|---|---|
| Elongation at break after | A | A | A | A | A | A |
| curing *2 | | | | | | |
| Elongation at break after | A | B | A | A | A | A |
| storage at high | | | | | | |
| temperature (180° C.) *3 | | | | | | |
| Cracking in cured product | ∘ | ∘ | ∘ | ∘ | ∘ | ∘ |
| (180° C.) *4 | | | | | | |
| Cracking in cured product | ∘ | x | ∘ | x | ∘ | ∘ |
| (200° C.) *5 | | | | | | |

| | | Comparative | Comparative | Comparative | Reference |
|---|---|---|---|---|---|
| | | Example 1 | Example 5 | Example 6 | Example 1 |
| PDMS having | Mn | 20,000 | 32,000 | 32,000 | 22,000 |
| silanol groups at | Mw/Mn | 2.02 | 2.57 | 1.81 | 1.15 |
| both ends | | | | | |
| oligomer of TEOS | | n = 4~6 | n = 8~10 | n = 8~10 | n = 8~10 |
| (n-mer: linear) | | | | | |
| PDMS/oligomer of TEOS | | 1/4 | 1/3 | 1/1 | 1/3 |
| (molar ratio) | | | | | |
| Toluene content (ppm) *1 | | Less than 10 | Less than 10 | Less than 10 | 100 |
| Light | 200 nm | 3.0 | 0.4 | 3.9 | 2.1 |
| transmissivity | 250 nm | 86.5 | 90.3 | 84.2 | 83.9 |
| (%) (thickness | 300 nm | 93.0 | 94.5 | 92.7 | 95.2 |
| 0.5 mm) | 350 nm | 96.9 | 98.1 | 96.2 | 98.0 |
| | 400 nm | 97.9 | 98.6 | 97.4 | 98.6 |

| | | | | |
|---|---|---|---|---|
| Elongation at break *2 | B | A | C | — |
| Elongation at break after | C | B | C | — |
| storage at high | | | | |
| temperature (180° C.) *3 | | | | |
| Cracking in cured product | x | ∘ | x | — |
| (180° C.) *4 | | | | |
| Cracking in cured product | — | ∘ | x | — |
| (200° C.) *5 | | | | |

*1 Toluene concentration in PDMS having silanol groups at both ends
*2 A: more than 200%, B: 200-150%, C: less than 150%
*3 Evaluated after storage at 180° C. for 200 hours, A: more than 200%, B: 200-150%, C: less than 150%
*4 Observed after storage at 180° C. for 1,000 hours ∘: no cracking, x: Cracked
*5 Observed after storage at 200° C. for 1,000 hours ∘: no cracking, x: Cracked

[Evaluation Result]

In Examples 1 to 6, the light transmissivity in the UV region (at 250 nm) was very good, and the elongation at break was sufficient even after storage at 180° C. for 200 hours, and no cracking occurred in the cured product even after storage for 1,000 hours. In Example 2, no cracking occurred in the cured product even after storage for 5,000 hours. In addition, even after storage at higher temperature (200° C.) for 1,000 hours, no cracking occurred in the cured bodies in Examples 1, 3, 5, and 6.

On the other hand, in Comparative Examples 1, 5, and 6, the light transmissivity in the UV region (at 250 nm) was poor (less than 95%), and the elongation at break in Comparative Examples 1 and 6 was less than 150% after storage at 180° C. for 200 hours, and cracking occurred in the cured product after storage for 1,000 hours.

### SUMMARY

From the above results, the hybrid materials of Examples 1 to 6 according to the present invention have higher light transmissivity in almost all the wavelength regions including the UV region (at 250 nm), and thus have better properties than the prior art materials of Comparative Examples 1 to 4. Accordingly, as in Examples 1 to 6, the use of PDMS having uniform molecular weight (more specifically, the distribution index of molecular weight is 1.7 or less, preferably 1.3 or less, and more preferably 1.1 or less) achieves high heat resistance and high light transmissivity even after storage at high temperatures, and thus provides a hybrid material which uniformly transmits light as an optical film.

In Reference Example 1, the light transmissivity in the UV region (at 250 nm) is less than 95%, which is inferior to that in Example 1, indicating that the reduction of the toluene content in PDMS is preferred.

### Modified Example

The present invention will not be limited to the above-described Examples alone, and may be changed, deleted, or added without departing from the technical ideas of the present invention which can be recognized by those skilled in the art from Claims and explanations in the description.

In addition, the above-described Examples are not restrictive, and may use organometallic compounds of different types and having different properties.

### INDUSTRIAL APPLICABILITY

The organic-inorganic hybrid polymer of the present invention provides a cured product (sealed body) having high heat resistance (flexibility) and light transmissivity in the UV region, and the hybrid polymer has industrial applicability because it is useful as a sealant for UV-LEDs and other heat-generating element members, or as an adhesive.

1. An organic-inorganic hybrid prepolymer produced by condensation reaction between the following (A) and one or more compounds (B) selected from the group consisting of the following (B-1), (B-2), and (B-3):
(A): a polydimethylsiloxane having silanol groups at both ends, a number average molecular weight (Mn) of 10,000 or more and 100,000 or less, and a distribution index of molecular weight (Mw/Mn; Mw is weight average molecular weight) of 1.3 or less;
(B-1): an oligomer of tetraalkoxysilane;
(B-2): a complete or partial hydrolysate of the alkoxy groups of (B-1); and
(B-3): a condensation reaction product of (B-2) and (B-2), or (B-2) and (B-1).

2. The organic-inorganic hybrid prepolymer according to claim 1, which is obtained by adding 0.5 to 8 mols of the (B-1) to 1 mol of the (A), and subjecting them to condensation reaction.

3. The organic-inorganic hybrid prepolymer according to claim 1, wherein the residual amount of the organic solvent in the (A) is 50 ppm or less.

4. The organic-inorganic hybrid prepolymer according to claim 1, wherein the (B-1) is a linear tetramer to decamer.

5. The organic-inorganic hybrid prepolymer according to claim 1, wherein the (B-1) has a purity of 65% by mass or more.

6. An organic-inorganic hybrid polymer which is a cured product obtained by heat-curing the organic-inorganic hybrid prepolymer (C) according to claim 1.

7. The organic-inorganic hybrid polymer according to claim 6, wherein the organic-inorganic hybrid prepolymer (C) is heat-cured in the presence of an organometallic compound-containing solution (D).

8. The organic-inorganic hybrid polymer according to claim 7, wherein the organometallic compound-containing solution (D) is a solution containing an organometallic compound (E) and the (A).

9. The organic-inorganic hybrid polymer according to claim 7, wherein the organometallic compound (E) is one or more compounds selected from the group consisting of organic acid metal salts, metal alkoxides, alkylmetal compounds, acetylacetonate metal complexes, ethyl acetoacetate metal complexes, and metal complexes substituted with acetylacetonate or ethyl acetoacetate at one or more alkoxy groups of metal alkoxide.

10. The organic-inorganic hybrid polymer according to claim 7, wherein the organometallic compound (E) is at least one mixture selected from the group consisting of mixtures of zirconium carboxylate and zinc carboxylate, and mixtures of zirconyl carboxylate and zinc carboxylate.

11. The organic-inorganic hybrid polymer according to claim 7, wherein the mixing ratio of the organic-inorganic hybrid prepolymer (C) to the organometallic compound-containing solution (D) is from 100:0.1 to 100:20 in terms of the mass ratio of (C):(D).

12. The organic-inorganic hybrid polymer according to claim 6, wherein the organic-inorganic hybrid polymer (F) in the form of a plate-shaped body transmits 60% or more of light having a wavelength of 200 nm, and 95% or more of light having a wavelength of 250 nm in the thickness direction.

13. The organic-inorganic hybrid polymer according to claim 6, wherein the organic-inorganic hybrid polymer (F) has an elongation at break of 150% or more as measured by the tensile test in accordance with JIS K6251.

14. A sealant for LED elements, comprising the organic-inorganic hybrid prepolymer (C) according claim 1.

15. A sealing structure comprising LED elements sealed with the organic-inorganic hybrid polymer according to claim 6.
